(19) United States
(12) Patent Application Publication
(10) Pub. No.: US 2010/0116860 A1
(43) Pub. Date: May 13, 2010

(54) Backpack Laptop Tray

(76) Inventor: Ricardo Tello, Santa Fe Springs, CA (US)

Correspondence Address: QUICKPATENTS, INC., 32861 CALLE PERFECTO, SUITE A, SAN JUAN CAPISTRANO, CA, 92675, US

(21) Appl. No.: 12/269,036

(22) Filed: Nov. 11, 2008

(51) Int. Cl. A45F 5/00; H05K 5/00; H05K 7/00; H05K 7/20

(52) U.S. Cl. 224/576; 224/153; 224/652; 224/653; 224/270; 361/679.03; 361/679.55; 361/688

(57) ABSTRACT

A backpack for storing and facilitating the use of a laptop computer by a user is disclosed. The backpack includes an enclosure having a front side, a back side, and at least one peripheral edge. The front side includes a laptop compartment flap that is hinged across a horizontal fold line and pivotable between a closed and an open position. The laptop compartment flap also includes a stop means preventing the laptop compartment flap from extending past the open position. With the laptop stored in the laptop compartment of the enclosure, the user may support the backpack in front of the user by the shoulders using shoulder straps, open the laptop compartment flap, remove the laptop and supported the laptop on an inside surface of the laptop compartment flap, with the weight of the laptop being supported by the flap and the stop means.

### CROSS-REFERENCE TO RELATED APPLICATIONS

Not Applicable.

### STATEMENT REGARDING FEDERALLY SPONSORED RESEARCH AND DEVELOPMENT

Not Applicable.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by any one of the patent disclosure as it appears in the Patent and Trademark Office patent files or records, but otherwise reserves all copyright and trade dress rights whatsoever.

### FIELD OF THE INVENTION

This invention relates to backpacks, and more particularly to a backpack particularly suited for carrying and facilitating use of a laptop computer.

### DISCUSSION OF RELATED ART

Laptop computers and similar computing devices are frequently carried in a variety of bags and/or cases. Such bags may be used to protect the laptop computers from minor impacts during transit, and to allow a user of the bag to have his or her hands free while transporting the laptop computer. While hand-held bags or briefcases, which may or may not include a shoulder strap, are frequently used to transport laptop computers, backpacks may also be used.

However the bag is carried, conventional laptop computer bags may cause inconvenience to users because the laptop computer must generally be removed from the bag entirely to be used. Because removing and replacing the laptop computer from the bag may entail removing the laptop computer from restraints and/or from a compartment designed for the laptop computer and/or shuffling around other contents of the bag, it can be time consuming and inefficient to the user. Furthermore, adjusting the bag's contents to remove or replace the laptop computer while traveling can increase the risk that the laptop computer is dropped, which can cause damage to the laptop computer that is expensive and time-consuming to repair.

Laptop bags are known in the art. For example, U.S. App. No. 20070159781 filed by Zbikowski on Jan. 5, 2007 describes a laptop computer bag (including a backpack embodiment) that includes a fold-out, desk-like portable workspace with extendable front and rear legs. Such a laptop computer bag requires time-consuming assembly of the portable workspace whenever the user wishes to utilize the workspace, causing inconvenience for the user. Also, the portable workspace, even when folded up, seems bulky and would add significant weight and size to the laptop computer bag, reducing the portability of the laptop computer bag and making the laptop computer bag impractical for elder, younger, and physically frail users.

U.S. Pat. No. 6,655,565 to Godshaw et al. filed on Mar. 29, 2001 describes a backpack that includes a storage enclosure divided by an interior front panel that permits access to the storage enclosure from the front of the backpack as well as the top of the backpack. Such an apparatus still requires removal of a laptop computer from the storage enclosure to be used, and furthermore does not provide any support for the laptop computer to be used.

U.S. Pat. No. 5,649,658 to Hoffman et al. filed on Mar. 3, 1995 describes a backpack with a fold-out infant changing pad contained in an auxiliary backpack compartment. The Hoffman patent does not address using a laptop in any way. Furthermore, the fold-out changing pad seemingly must be placed on a hard surface to be able to bear any substantial weight, and therefore does not provide any support that could be used to support a laptop computer.

Therefore, there is a need for a device that may be used as a laptop computer bag and can allow use of a laptop computer without requiring that the laptop computer be removed from the bag. Furthermore, such a device would not require much assembly by a user, provide sufficient support to bear the weight of the laptop computer during operation, and do so without any straps that would interfere with use of the laptop computer. The present invention accomplishes these objectives.

### SUMMARY OF THE INVENTION

The present device is a backpack for storing and facilitating the use of a laptop computer by a user. The backpack includes an enclosure having a front side, a back side, and at least one peripheral edge, where the sides and edges together define an internal volume. The front side includes a laptop compartment flap selectively closable to seal a laptop compartment that makes up at least a portion of the volume of the enclosure. The laptop compartment flap is hinged across a horizontal fold line and pivotable between a closed and an open position. The laptop compartment flap also includes a stop means preventing the laptop compartment flap from extending past the open position.

The back pack also includes a pair of shoulder straps fixed to the back side of the enclosure for encircling the user's shoulders to be supported thereby. With the laptop stored in the laptop compartment of the enclosure, the user may support the backpack in front of the user by the shoulders using the shoulder straps, the laptop compartment flap being selectively opened, the laptop removed and supported on an inside surface of the laptop compartment flap, the weight of the laptop being supported by the flap and the stop means, and the user's hands being thereby unencumbered when using the laptop computer.

In an exemplary embodiment, the stop means may include a rigid member fixed at least partially within the laptop compartment flap and at least partially within the enclosure, the enclosure further including a channel for receiving the rigid member and allowing pivotal travel thereof only through a predefined arch therein.

The present invention may be used as a laptop computer bag and can allow use of a laptop computer without requiring that the laptop computer be removed from the bag. Furthermore, the present invention does not require much assembly by a user, and provides sufficient support to bear the weight of the laptop computer during operation. The present invention can do so without any straps that would interfere with use of the laptop computer. Other features and advantages of the present invention will become apparent from the following more detailed description, taken in conjunction with the accompanying drawings, which illustrate, by way of example, the principles of the invention.

### DESCRIPTION OF THE DRAWINGS

FIG. 1 is a perspective view of an exemplary embodiment of a backpack for storing and facilitating the use of a laptop computer with a laptop compartment flap in a closed position;

FIG. 2 is a perspective view of the invention, illustrating an exemplary embodiment wherein the laptop compartment flap is in an open position;

FIG. 3 illustrates a side view of the invention in use;

FIG. 4 illustrates a partially transparent view of a stop means of the invention that includes a rigid member that is allowed to travel only through a defined arc;

FIG. 5 illustrates a partial front view of the invention;

FIG. 6 illustrates a partial cross-section cut-away view of the invention wherein the laptop compartment flap is in a closed position;

FIG. 7 illustrates a bottom perspective view of the rigid member and a stop means of the invention; and

FIG. 8 is a partial side elevational view wherein the laptop compartment is lined with a resilient shock-absorbing material.

### DETAILED DESCRIPTION OF THE PREFERRED EMBODIMENT

Illustrative embodiments of the invention are described below. The following explanation provides specific details for a thorough understanding of and enabling description for these embodiments. One skilled in the art will understand that the invention may be practiced without such details. In other instances, well-known structures and functions have not been shown or described in detail to avoid unnecessarily obscuring the description of the embodiments.

Unless the context clearly requires otherwise, throughout the description and the claims, the words “comprise,” “comprising,” and the like are to be construed in an inclusive sense as opposed to an exclusive or exhaustive sense; that is to say, in the sense of “including, but not limited to.” Words using the singular or plural number also include the plural or singular number respectively. Additionally, the words “herein,” “above,” “below” and words of similar import, when used in this application, shall refer to this application as a whole and not to any particular portions of this application. When the claims use the word “or” in reference to a list of two or more items, that word covers all of the following interpretations of the word: any of the items in the list, all of the items in the list and any combination of the items in the list.

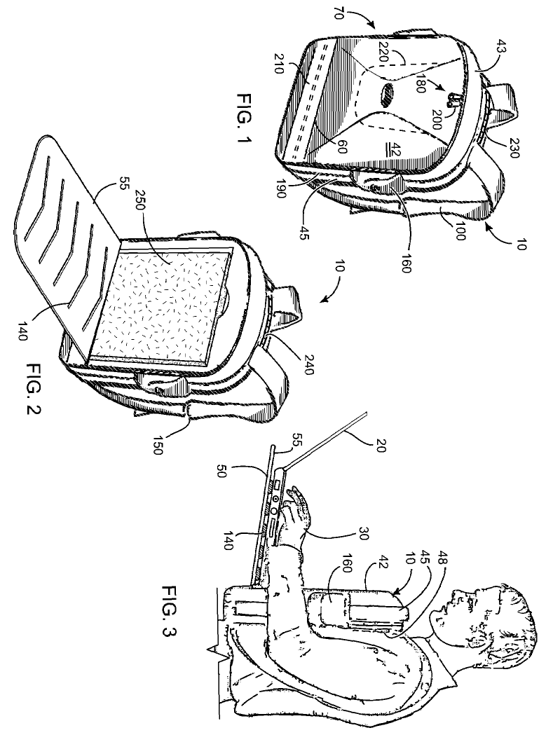

FIG. 1 is a perspective view of an exemplary embodiment of a backpack 10 for storing and facilitating the use of a laptop computer 20 with a closed laptop compartment flap 55. The backpack 10 includes an enclosure (e.g., the bag portion of the backpack 10) having a front side 42, a back side 48, and at least one peripheral edge 45, the sides and edges 42,48,45 together defining an internal volume 90. The peripheral edge 45 can be a single piece that wraps around the entire backpack 10, as shown in FIG. 1, or can include several discrete pieces. The backpack 10 may, in some embodiments, include a top side 43 as well coupled to the front side 42 and the back side 48 (not shown in FIG. 1) that is located on the top side 43 of the backpack 10. The top side 43 may, in an exemplary embodiment, include a selectively sealable top compartment 230, which may conserve space in the internal volume 90 and add to the storage capacity of the backpack 10.

The front side 42 includes a laptop compartment flap 55 hinged across a horizontal fold line 60 pivotable between a closed position 70 and an open position 80. The laptop compartment flap 55 is shown in the closed position 70 in FIG. 1. The laptop compartment flap 55 includes a stop means 90 preventing the laptop compartment flap 55 from extending past the open position 80, which shall be described in further detail below.

The backpack 10 also includes a pair of shoulder straps 100 fixed to the back side 48 of the enclosure 40 for encircling the user's shoulders to be supported thereby. As will be described below, with the laptop computer 20 stored in the laptop compartment 50 of the enclosure 40, the user may support the backpack 10 in front of the user by the shoulders using the shoulder straps 100, the laptop compartment flap 55 being selectively opened, the laptop 20 removed and supported on an inside surface 56 of the laptop compartment flap 55, the weight of the laptop 20 being supported by the flap 55 and the stop means 90, the user's hands being thereby unencumbered when using the laptop computer 20.

The backpack 10 may thereby be used as a laptop computer bag and allow use of the laptop computer 20 without requiring that the laptop computer 20 be fully removed from the backpack 10, since the laptop computer 20 is supported on the inside surface of the laptop compartment flap 55. Furthermore, the backpack 10 does not require substantial assembly by a user since to use the laptop computer 20 the user need only open the laptop compartment flap 55 and place the laptop computer 20 thereon. The backpack 10 provides sufficient support to bear the weight of the laptop computer 20 during operation, without using any straps that would interfere with use thereof, because the weight of the laptop computer 20 is supported by the flap 55 and the stop means 90. No external hard surface is needed, nor is there a need for a table-like setup requiring user assembly.

The backpack 10 may additionally include other elements that may improve the functionality of the backpack 10. For example, the backpack 10 may further including at least one selectively sealable pocket 160 on the peripheral edge 45 of the enclosure 40, which may be used to store smaller items or laptop accessories (not shown), thereby conserving space in the internal volume 49 and/or adding to the storage capacity of the backpack 10. In an exemplary embodiment, the backpack 10 may also include a sealing means 180 adapted to allow the selective closure of the laptop compartment flap 55 with the enclosure 40. The sealing means 180 may keep the laptop compartment flap 55 in the closed position 70 so that it is not accidentally opened, and may be any suitable device or combination of devices that can seal the laptop compartment flap 55. In the embodiment shown in FIG. 1, the sealing means 180 is a two-part mechanical fastener 190, such as a zipper 200.

Also, in an exemplary embodiment, the backpack 10 may further include a selectively sealable front pocket 210 on the front side 42 of the enclosure below the horizontal fold line 60 of the laptop compartment flap 55, the front pocket further 210 supporting the laptop compartment flap 55 when the laptop compartment flap 55 is in the open position 80. The selectively sealable front pocket 210 may provide this support, for example, by being composed of a rigid or semi-rigid material, such as hard plastic, metal wire, or a similar material, and may be used to contain small items as well, thereby conserving space in the internal volume 49 and adding to the storage capacity of the backpack 10.

In another exemplary embodiment, the backpack 10 may further include a second selectively sealable front pocket 220 on the front side 42 of the enclosure 40 above the horizontal fold line 60 of the laptop compartment flap 55. The second selectively sealable front pocket 220 may also be used to contain small items and thereby conserve space in the internal volume 49 and add to the storage capacity of the backpack 10.

FIG. 2 is a perspective view of the invention, illustrating of an exemplary embodiment wherein the laptop compartment flap 55 is in the open position 80. The laptop compartment flap 55 is selectively closable to seal the laptop compartment 50 that includes at least a portion of the volume of the enclosure 40. The laptop compartment flap 55, as stated above, is hinged across the horizontal fold line 60 and pivotable between the closed and open positions 70,80, respectively. The laptop compartment flap 55 including the stop means 90 preventing the laptop compartment flap 55 from extending past the open position shown in FIG. 2. In addition to the laptop compartment 50, the backpack 10 may in an exemplary embodiment include at least one additional compartment 57 comprising at least another portion of the internal volume of the enclosure 40. An example of the at least one additional compartment 57 may be seen in FIG. 8.

The backpack shown in FIG. 2 also illustrates an exemplary embodiment wherein the laptop compartment flap 55 includes an inside surface 56 that further includes a plurality of heat sink strips 140 fixed thereto, whereby heat from the laptop 20 when resting on the heat sink strips 140 allows air to enter between two of the heat sink strips 140 to convey heat from the laptop 20 upwards and out from between the laptop 20 and the laptop compartment flap 55. The heat sink strips 140 may be advantageous to prevent the laptop computer 20 from overheating when used with the backpack 10. In an exemplary embodiment, the plurality of heat sink strips 140 may each be pivotally fixed to the laptop compartment flap 55, such that each heat sink strip may be pivoted towards an edge of the inside surface 56 of the laptop compartment flap 55 so that the inside surface 56 may further serve as a flat writing surface, further adding to the functionality of the backpack 10.

Also shown in the exemplary embodiment depicted in FIG. 2 are a pair of shoulder straps 100, each including an adjustable buckle means 150. The adjustable buckle means 150 allows the length of the shoulder straps 100 to be adjusted to account for a user-desired comfort level, and may also be pivoted out of the way when the backpack 10 is worn in front of the user (e.g., while the laptop is being used). The adjustable buckle means 150 may be any suitable device that allows the length of the shoulder straps 100 to be adjusted (e.g., a buckle and/or a locking device). Clearly the backpack 10 may be worn conventionally on the back of the user (not shown) when the laptop 20 is not in use.

The backpack 10 in FIG. 2 also displays an exemplary embodiment that further includes a carrying handle 240 fixed to the top side of the enclosure 40. The carrying handle 240 is capable of bearing the weight of the backpack 10 and may permit a user to carry the backpack 10 using his or her hands. The backpack in FIG. 2 also displays an exemplary embodiment wherein the laptop compartment 50 is lined with a resilient shock-absorbing material 250. The resilient shock-absorbing material 250 can reduce the force of impacts with the backpack 10 upon the laptop computer 20, which may be sensitive to such impacts. The shock-absorbing material 250 may be composed of any suitable material, including foam, cloth, and/or a gel enclosed in a separate bag, and may be deployed in any configuration that provides support and reduces the force of impacts upon the laptop computer 20.

FIG. 3 illustrates a side view of an exemplary embodiment of the invention in use. The backpack 10 for storing and facilitating the use of the laptop computer 20 by the user 30 includes the enclosure 40 having the front side 42, the back side 48, and the at least one peripheral edge 45, the sides and edges together defining the internal volume 49. FIG. 3 shows the user 30 supporting the backpack 10 in front of the user 30 by the shoulders using the shoulder straps 100. The laptop compartment flap 55 is illustrated in its open position 80, the laptop 20 is removed (from the laptop compartment 50 in the exemplary embodiment shown) and supported on the inside surface 56 of the laptop compartment flap 55, the weight of the laptop 20 being supported by the flap 55 and the stop means 90. As shown in FIG. 3, the user's hands are thereby unencumbered when using the laptop computer 20. Additional elements shown in FIG. 3 include the least one selectively sealable pocket 160 on the peripheral edge of the enclosure, described above, and the plurality of heat sink strips 140 fixed to the inside surface of the laptop compartment flap 55. FIG. 3 clearly illustrates the spaces between the heat sink strips 140, which may allow air to enter between two of the heat sink strips 140 to convey heat from the laptop 20 upwards and out from between the laptop 20 and the laptop compartment flap 55.

Preferably the width of the peripheral edge 45 of the backpack 10 is such that the user 30 is able to easily reach around the backpack 10 when worn on the user's front side, as illustrated in FIG. 3. Likewise, the height of the backpack 10 overall must not be so high that the top of the top side 43 thereof obscures the user's view of the laptop 20 when in use. A ratio of the overall backpack height to the peripheral edge 45 width may be 4:1, for example.

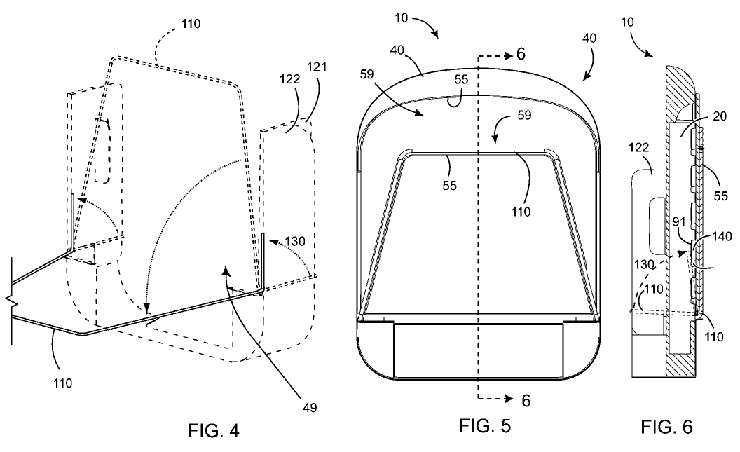

FIG. 4 illustrates a stop means 90 of the invention that includes a rigid member 110 that is allowed to travel only through a defined arc 130. Because the front side 42, the back side 48, and the at least one peripheral edge 45 of the enclosure 40 are transparent in FIG. 4, the internal volume 49 defined by the sides 42,48 and edges 45 together may be seen. In an exemplary embodiment, the stop means 90 preventing the laptop compartment flap 55 from extending past the open position may include a rigid member 110 fixed at least partially within the laptop compartment flap 55 and at least partially within the enclosure 40. The rigid member 110 may be of sufficient rigidity to support the weight of the laptop computer 20 when in the open position, meaning that it does not deform or break under the weight of the laptop computer 20. The rigid member 110 may be made of any suitable material, such as metal or plastic, and may be a wire extending around the perimeter of the laptop compartment flap 55, for example. In such embodiments, the rigid member 110 may also be shaped and sized appropriately so that the laptop computer 20 rests on the rigid member 110 on both sides of the laptop compartment flap 55, and does not fall between the two sides. In another embodiment, the rigid member 110 may be a solid plate extending beneath the entirety of the laptop compartment flap 55. The rigid member 110 is shown in the closed position 70 (using a dashed line) and in the open position 80 (the solid line) in FIG. 4.

The enclosure may further including a channel 120 for receiving the rigid member 110 and allowing pivotal travel thereof only through a predefined arch 130 therein. In an exemplary embodiment, the channel 120 receives the end portion of the rigid member 110 at each side of the backpack 10, and inhibits the movement of the rigid member 110 after it reaches the end of the predefined arch 130. The predefined arch 130 can be one-fourth of a full 360-degree rotation, thereby causing the laptop compartment flap 55 to form a 90-degree angle with the enclosure 40 as shown in FIG. 4. In an exemplary embodiment, the channel 120 can have a plurality of grooves, thereby allowing the user 30 to select between a plurality of predefined arches 130 to suit the user's preferences. This can be advantageous, for example, if the user wishes to adjust the viewing angle of the laptop computer 20 based upon the user's seating position.

FIG. 5 illustrates a partial front view of the invention. The backpack 10 includes the enclosure 40, wherein the front side 42 is partially transparent. The front side 42 includes the laptop compartment flap 55 selectively closable to seal a laptop compartment 59 that makes up at least a portion of the internal volume 49 of the enclosure 40. The remainder of the internal volume 49 may be used to store additional items 270 (not shown in FIG. 5) separately from the laptop computer 20. Having the laptop computer 20 in a separate laptop compartment 59 can facilitate removal of the laptop computer when in use. FIG. 5 also displays the rigid member 110 in the closed position.

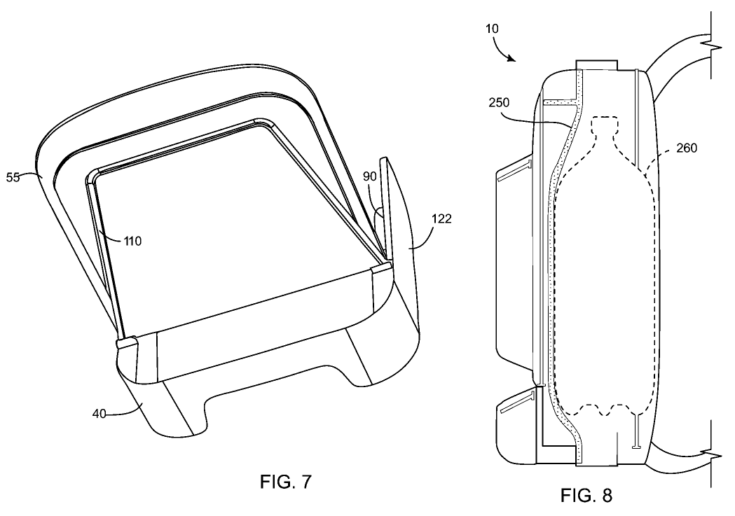

FIG. 6 illustrates a partial cross-section cut-away view of an exemplary embodiment of the invention wherein the laptop compartment flap 55 is in a closed position. FIG. 6 shows the laptop computer 20 in the laptop compartment 59, where it is held so that it is substantially unable to move about when the backpack 10 is moved by laptop compartment flap 55, which includes the rigid member 110 and the heat sink strips 140 that function as described above in the embodiment shown in FIG. 6. The backpack 10 shown in FIG. 6 also includes the channel 120 for receiving the rigid member 110 that allowing pivotal travel thereof only through the predefined arch 130 therein when the laptop compartment flap 55 is in the open position 80. While the channel 122 is shown to have a particular shape in FIG. 6, the present invention is not limited in this regard, and may have any suitable shape that allows pivotal travel through the predefined arch 130 (e.g., a triangular shape, a rectangular shape, etc.).

FIG. 7 illustrates a bottom perspective view of the rigid member 110 and the stop means 90 of the invention. FIG. 7 shows the enclosure 40, wherein the laptop compartment flap 55 is in the open position 80. In the exemplary embodiment displayed in FIG. 7, the stop means 90 preventing the laptop compartment flap 55 from extending past the open position includes the rigid member 110, which is fixed at least partially within the laptop compartment flap 55 and at least partially within the enclosure 40. The channel 120 is shown in FIG. 7 as well, which functions as described above.

FIG. 8 is a partial side elevational view wherein the laptop compartment 59 is lined with a resilient shock-absorbing material 250, which functions as described above. Additionally, FIG. 8 shows an exemplary embodiment of a backpack with a partition wall 260 within the enclosure separating the laptop compartment 59 from the at least one additional compartment 57. Additionally, in the exemplary embodiment, the partition wall 260 is flexible and made at least partially from the shock-absorbing material 250, such that the partition wall 260 is able to expand into the at least one additional compartment 57 to create more volume in the laptop compartment 59, and the partition wall 260 is further able to expand into the laptop compartment 59 to create more volume in the at least one additional compartment 57. Having a flexible partition wall 260 permits more flexibility for the user in arranging items 270 into the enclosure 40, for example, if the user is not carrying a laptop computer, or if the user wishes to carry additional items in the laptop compartment 50.

While a particular form of the invention has been illustrated and described, it will be apparent that various modifications can be made without departing from the spirit and scope of the invention. For example, instead of using a pair of substantially identical shoulder straps 100 as shown in FIGS. 1 and 3, two unequally sized shoulder straps may be used with an adjustable harness connecting the two. Accordingly, it is not intended that the invention be limited, except as by the appended claims.

The teachings provided herein can be applied to other systems, not necessarily the system described herein. The elements and acts of the various embodiments described above can be combined to provide further embodiments. All of the above patents and applications and other references, including any that may be listed in accompanying filing papers, are incorporated herein by reference. Aspects of the invention can be modified, if necessary, to employ the systems, functions, and concepts of the various references described above to provide yet further embodiments of the invention.

These and other changes can be made to the invention in light of the above Detailed Description. While the above description details certain embodiments of the invention and describes the best mode contemplated, no matter how detailed the above appears in text, the invention can be practiced in many ways. Details of the system may vary considerably in its implementation details, while still being encompassed by the invention disclosed herein.

Particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific embodiments disclosed in the specification, unless the above Detailed Description section explicitly defines such terms. Accordingly, the actual scope of the invention encompasses not only the disclosed embodiments, but also all equivalent ways of practicing or implementing the invention.

The above detailed description of the embodiments of the invention is not intended to be exhaustive or to limit the invention to the precise form disclosed above or to the particular field of usage mentioned in this disclosure. While specific embodiments of, and examples for, the invention are described above for illustrative purposes, various equivalent modifications are possible within the scope of the invention, as those skilled in the relevant art will recognize. Also, the teachings of the invention provided herein can be applied to other systems, not necessarily the system described above. The elements and acts of the various embodiments described above can be combined to provide further embodiments.

All of the above patents and applications and other references, including any that may be listed in accompanying filing papers, are incorporated herein by reference. Aspects of the invention can be modified, if necessary, to employ the systems, functions, and concepts of the various references described above to provide yet further embodiments of the invention.

Changes can be made to the invention in light of the above “Detailed Description.” While the above description details certain embodiments of the invention and describes the best mode contemplated, no matter how detailed the above appears in text, the invention can be practiced in many ways. Therefore, implementation details may vary considerably while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated.

In general, the terms used in the following claims should not be construed to limit the invention to the specific embodiments disclosed in the specification, unless the above Detailed Description section explicitly defines such terms. Accordingly, the actual scope of the invention encompasses not only the disclosed embodiments, but also all equivalent ways of practicing or implementing the invention under the claims.

While certain aspects of the invention are presented below in certain claim forms, the inventor contemplates the various aspects of the invention in any number of claim forms. Accordingly, the inventor reserves the right to add additional claims after filing the application to pursue such additional claim forms for other aspects of the invention.

What is claimed is:

1. A backpack for storing and facilitating the use of a laptop computer by a user, comprising:
an enclosure having a front side, a back side, an at least one peripheral edge, the sides and edges together defining an internal volume, the front side including a laptop compartment flap selectively closable to seal a laptop compartment comprising at least a portion of the volume of the enclosure, the laptop compartment flap hinged across a horizontal fold line and pivotable between a closed and an open position, the laptop compartment flap including a stop means preventing the laptop compartment flap from extending past the open position;
a pair of shoulder straps fixed to the back side of the enclosure for encircling the user's shoulders to be supported thereby;
whereby with the laptop stored in the laptop compartment of the enclosure, the user may support the backpack in front of the user by the shoulders using the shoulder straps, the laptop compartment flap being selectively opened, the laptop removed and supported on an inside surface of the laptop compartment flap, the weight of the laptop being supported by the flap and the stop means, the user's hands being thereby unencumbered when using the laptop computer.

2. The backpack of claim 1 wherein the stop means includes a rigid member fixed at least partially within the laptop compartment flap and at least partially within the enclosure, the enclosure further including a channel for receiving the rigid member and allowing pivotal travel thereof only through a predefined arch therein.

3. The backpack of claim 1 wherein the laptop compartment flap includes an inside surface that further includes a plurality of heat sink strips fixed thereto, whereby heat from the laptop when resting on the heat sink strips allows air to enter between two of the heat sink strips to convey heat from the laptop upwards and out from between the laptop and the laptop compartment flap.

4. The backpack of claim 1 wherein the plurality of heat sink strips are each pivotally fixed to the laptop compartment flap, such that each heat sink strip may be pivoted towards an edge of the inside surface of the laptop compartment flap so that the inside surface may further serve as a flat writing surface.

5. The backpack of claim 1 wherein each shoulder strap includes an adjustable buckle means.

6. The backpack of claim 1 further including at least one selectively sealable pocket on the peripheral edge of the enclosure.

7. The backpack of claim 1 further including at least one additional compartment comprising at least another portion of the internal volume of the enclosure.

8. The backpack of claim 1 further including a sealing means adapted to allow the selective closure of the laptop compartment flap with the enclosure.

9. The backpack of claim 8 wherein the sealing means is a two-part mechanical fastener.

10. The backpack of claim 9 wherein the sealing means is a zipper.

11. The backpack of claim 1 further including a selectively sealable front pocket on the front side of the enclosure below the horizontal fold line of the laptop compartment flap, the front pocket further supporting the laptop compartment flap when the laptop compartment flap is in the open position.

12. The backpack of claim 1 further including a second selectively sealable front pocket on the front side of the enclosure above the horizontal fold line of the laptop compartment flap and on an outside surface thereof.

13. The backpack of claim 1 further including a selectively sealable top compartment in a top side of the enclosure.

14. The backpack of claim 1 further including a carrying handle fixed to the top side of the enclosure.

15. The backpack of claim 1 wherein the laptop compartment is lined with a resilient shock-absorbing material.

16. The backpack of claim 7 further including a partition wall within the enclosure separating the laptop compartment from the at least one additional compartment.

17. The backpack of claim 16 wherein the partition wall is flexible such that the partition wall is able to expand into the at least one additional compartment to create more volume in the laptop compartment, the partition wall further able to expand into the laptop compartment to create more volume in the at least one additional compartment.
